(19) United States
(12) Patent Application Publication
(10) Pub. No.: US 2025/0125239 A1
(43) Pub. Date: Apr. 17, 2025

(54) INTERCONNECT SUBSTRATE AND METHOD OF MAKING THE SAME

(71) Applicant: SHINKO ELECTRIC INDUSTRIES CO., LTD., Nagano (JP)

(72) Inventors: Yuji YUKIIRI, Nagano (JP); Kenta NAKAMURA, Nagano (JP)

(21) Appl. No.: 18/912,838

(22) Filed: Oct. 11, 2024

(30) Foreign Application Priority Data
Oct. 17, 2023 (JP) 2023-178557

(51) Int. Cl. H01L 23/498; H05K 1/03; H05K 1/11

(52) U.S. Cl. CPC H01L 23/49822; H05K 1/0373; H05K 1/115; H05K 2201/09827

(57) ABSTRACT

An interconnect substrate includes a first interconnect layer, an insulating layer formed on the interconnect layer and containing a filler, a via hole penetrating the insulating layer and reaching an upper surface of the first interconnect layer, and a second interconnect layer filling the via hole and electrically connected to the first interconnect layer, wherein the insulating layer includes a first layer covering the first interconnect layer and a second layer laminated on, and thinner than, the first layer, an amount of the filler in the second layer being smaller than in the first layer, an inner surface of the via hole being inclined relative to a direction perpendicular to the upper surface, an angle of the inner surface of the via hole in the first layer with respect to the upper surface being larger than an angle of the inner surface of the via hole in the second layer.

### CROSS-REFERENCE TO RELATED APPLICATIONS

The present application is based upon and claims the benefit of priority from the prior Japanese Patent Application No. 2023-178557 filed on Oct. 17, 2023, with the Japanese Patent Office, the entire contents of which are incorporated herein by reference.

### FIELD

The disclosures herein relate to interconnect substrates and methods of making the same.

### BACKGROUND

An interconnect substrate as known in the art has a build-up structure in which a plurality of insulating layers and a plurality of interconnect layers are alternately laminated to form a multilayer structure. Such an interconnect substrate may utilize an insulating layer structure that includes a lower insulating layer and an upper insulating layer provided on the lower insulating layer. The upper insulating layer and the lower insulating layer contain, for example, an inorganic material within a resin insulating material, and the upper insulating layer is formed to be thinner than the lower insulating layer. The volume ratio of the inorganic material to the upper insulating layer is smaller than the volume ratio of the inorganic material to the lower insulating layer (see Patent Document 1, for example).

With a small volume ratio of the inorganic material to the upper insulating layer, however, a via hole formed in the insulating layer tends to have a large opening diameter at the upper surface of the upper insulating layer. As a result, the interval between adjacent via holes becomes narrow, which gives rise to a risk that adjacent interconnects formed on the upper insulating layer are short-circuited.

Accordingly, there may be a need to provide an interconnect substrate in which the risk of short-circuiting between adjacent interconnects is reduced.

### RELATED-ART DOCUMENT

### Patent Document

[Patent Document 1] Japanese Laid-open Patent Publication No. 2015-122545

### SUMMARY

According to an aspect of the embodiment, an interconnect substrate includes a first interconnect layer, an insulating layer formed on the first interconnect layer and containing a filler, a via hole penetrating the insulating layer and reaching an upper surface of the first interconnect layer, and a second interconnect layer filling the via hole and electrically connected to the first interconnect layer, the second interconnect layer extending from inside the via hole and along an upper surface of the insulating layer, wherein the insulating layer includes a first insulating layer covering the first interconnect layer and a second insulating layer laminated on the first insulating layer, the second insulating layer is thinner than the first insulating layer, an amount of the filler contained in the second insulating layer is smaller than an amount of the filler contained in the first insulating layer, in cross-sectional view, an inner surface of the via hole is inclined relative to a direction perpendicular to the upper surface of the first interconnect layer, in the cross-sectional view, an angle of the inner surface of the via hole in the first insulating layer with respect to the upper surface of the first interconnect layer is larger than an angle of the inner surface of the via hole in the second insulating layer with respect to the upper surface of the first interconnect layer.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are cross-sectional views illustrating an example of an interconnect substrate according to a first embodiment;

FIGS. 2A through 2D are drawings illustrating an example of a manufacturing process of the interconnect substrate according to the first embodiment;

FIGS. 3A through 3D are drawings illustrating an example of the manufacturing process of the interconnect substrate according to the first embodiment; and

FIGS. through 4C are drawings 4A illustrating an example of the manufacturing process of the interconnect substrate according to the first embodiment.

### DESCRIPTION OF EMBODIMENTS

In the following, an embodiment of the invention will be described with reference to the accompanying drawings. In these drawings, the same components are referred to by the same reference numerals, and duplicate descriptions may be omitted.

### First Embodiment

### [Structure of Interconnect Substrate]

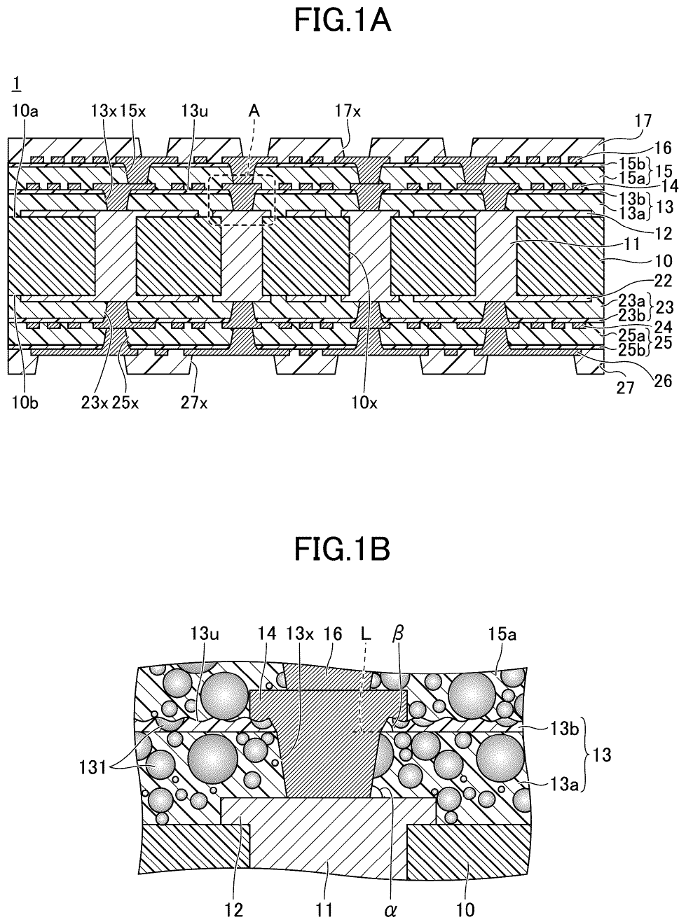

FIGS. 1A and 1B are cross-sectional views illustrating an example of an interconnect substrate according to a first embodiment. FIG. 1A is an overall view, and FIG. 1B is an enlarged view of a portion A in FIG. 1A.

Referring to FIGS. 1A and 1B, an interconnect substrate 1 has a structure in which interconnect layers and insulating layers are laminated on both surfaces of a core layer 10.

Specifically, the interconnect substrate 1 includes an interconnect layer 12, an insulating layer 13, an interconnect layer 14, an insulating layer 15, an interconnect layer 16, and a solder resist layer 17 sequentially laminated on the first surface 10a of the core layer 10. On the second surface 10b of the core layer 10, an interconnect layer 22, an insulating layer 23, an interconnect layer 24, an insulating layer 25, an interconnect layer 26, and solder resist a layer 27 are sequentially laminated.

In the first embodiment, for the sake of convenience, the solder resist layer 17 side of the interconnect substrate 1 is referred to as an upper side or a first side, and the solder resist layer 27 side is referred to as a lower side or a second side. Further, the surface of an object on the upper side is referred to as a first surface or an upper surface, and the surface of the object on the lower side is referred to as a second surface or a lower surface. However, the interconnect substrate 1 may be used upside down, or may be arranged at any angle. The plan view refers to the view of an object as seen from the direction normal to the first surface 10a of the core layer 10, and the plane shape refers to the shape of an object as seen from the direction normal to the first surface 10a of the core layer 10.

The core layer 10 may be, for example, a glass-epoxy substrate or the like, in which a glass cloth is impregnated with an insulating resin such as an epoxy resin. The core layer 10 may alternatively be a substrate or the like made by impregnating a woven fabric or a nonwoven fabric such as glass fiber, carbon fiber, or aramid fiber with an epoxy resin or the like. The thickness of the core layer 10 is, for example, about 60 to 1000 μm. The core layer 10 has at least one through-hole 10x that penetrates the core layer 10 in the thickness direction. The plane shape of the through-hole 10x is, for example, circular.

The interconnect layer 12 is formed on the first surface 10a of the core layer 10. The interconnect layer 22 is formed on the second surface 10b of the core layer 10. The interconnect layer 12 and the interconnect layer 22 are electrically connected by a through interconnect 11 formed in the through-hole 10x. The interconnect layers 12 and 22 are patterned into predetermined plane shapes. As the materials of the interconnect layers 12 and 22 and the through interconnect 11, for example, copper (Cu) or the like may be used. The thicknesses of the interconnect layers 12 and 22 are, for example, each about 10 to 40 μm. The interconnect layers 12 and 22 and the through interconnect 11 may be formed as a seamless structure.

The insulating layer 13 is an interlayer insulating layer formed on the interconnect layer 12 on the first surface 10a of the core layer 10. The insulating layer 13 includes a first insulating layer 13a covering the upper surface and the side surfaces of the interconnect layer 12, and a second insulating layer 13b laminated on the first insulating layer 13a. The second insulating layer 13b is thinner than the first insulating layer 13a. The thickness of the first insulating layer 13a is, for example, 10 μm or more and 40 μm or less. The thickness of the second insulating layer 13b is, for example, 1 μm or more and 2 μm or less. The roughness of the upper surface 13u of the second insulating layer 13b is, for example, 250 nm or more and 300 nm or less in terms of the arithmetic average roughness Ra. With the arithmetic average roughness being in a Ra such range, interconnect floating and the like hardly occur, which allows the interconnect layer 14 to be stably formed on the second insulating layer 13b. The anchor effect effectively improves the adhesion between the second insulating layer 13b and the interconnect layer 14.

Each of the first insulating layer 13a and the second insulating layer 13b contains a filler 131. The filler 131 is, for example, silicon dioxide (SiO₂). The filler contained in each of the first insulating layer 13a and the second insulating layer 13b may alternatively be kaolin (Al₂Si₂O₅(OH₄)), talc (Mg₃Si₄O₁₀(OH₂)), alumina (Al₂O₃), or the like.

The type of filler 131 contained in each of the first insulating layer 13a and the second insulating layer 13b may be the same or different. The average grain size of the filler 131 contained in each of the first insulating layer 13a and the second insulating layer 13b may be the same or different. The filler 131 may have, for example, a minimum grain size of 0.1 μm, a maximum grain size of 5 μm, and an average grain size of about 0.5 to 2 μm. Part or all of the particles of the filler 131 may or may not be hollow.

The amount of the filler 131 contained in the first insulating layer 13a may be, for example, 70 wt % or more and 80 wt % or less. Setting the amount of the filler 131 contained in the first insulating layer 13a to 70 wt % or more effectively reduces the dielectric loss of the first insulating layer 13a, thereby enables the realization of an insulating layer with a small electrical loss. Further, setting the amount of the filler 131 contained in the first insulating layer 13a to 70 wt % or more effectively brings the thermal expansion coefficient of the first insulating layer 13a close to the thermal expansion coefficient (about 17 ppm/° C.) of copper (Cu) or the like constituting the interconnect layers 12 and 14, thereby makes it possible to reduce warping of the interconnect substrate 1.

The amount of the filler 131 contained in the second insulating layer 13b is smaller than the amount of the filler 131 contained in the first insulating layer 13a. The amount of the filler 131 contained in the second insulating layer 13b may be, for example, greater than 0 wt % and less than 70 wt %. With the amount of the filler 131 contained in the second insulating layer 13b being 70 wt % or more, the upper surface 13u of the second insulating layer 13b becomes filler-rich when the upper surface 13u of the second insulating layer 13b is etched in the desmear process described later. The fact that the upper surface 13u of the second insulating layer 13b becomes filler-rich reduces the adhesion with the interconnect layer 14, thereby giving rise to problems such as interconnect floating. Such interconnect floating causes a disconnection failure, resulting in the deterioration of the yield of the interconnect substrate. Setting the amount of the filler 131 contained in the second insulating layer 13b to less than 70 wt % reduces the risk of such problems occurring. The amount of the filler contained in the second insulating layer 13b is preferably less than 60 wt %, and more preferably less than 50 wt %. This arrangement further reduces the risk of the problems occurring.

The insulating resin used for the first insulating layer 13a and the second insulating layer 13b may be, for example, a thermosetting resin. Specifically, the insulating resin used for the first insulating layer 13a and the second insulating layer 13b may be, for example, an epoxy-based resin, an imide-based resin, a phenol-based resin, a cyanate-based resin, or the like. The insulating resin used for each of the first insulating layer 13a and the second insulating layer 13b may be the same or different. Use of the same insulating resin for each of the first insulating layer 13a and the second insulating layer 13b is preferable because of the improved adhesion therebetween.

The first insulating layer 13a may or may not contain a reinforcing member. The configuration without a reinforcing member in the first insulating layer 13a is preferable in terms of facilitating formation of a via hole 13x, which will be described later. The second insulating layer 13b does not contain a reinforcing member. The reinforcing member is, for example, a woven fabric or a nonwoven fabric of glass fiber, carbon fiber, aramid fiber, or the like.

The insulating layer 13 has at least one via hole 13x. The via hole 13x penetrates the insulating layer 13 and exposes the upper surface of the interconnect layer 12. The via hole 13x is, for example, a substantially inverted frusto-conical recess whose opening diameter on the insulating layer 15 side is larger than the diameter at the bottom end at the upper surface of the interconnect layer 12.

That is, in the cross-sectional view, the inner surface of the via hole 13x is inclined relative to the direction perpendicular to the upper surface of the interconnect layer 12 such that the via hole 13x widens with an increase in the distance from the interconnect layer 12 in the thickness direction. The inclination angle of the inner surface of the via hole 13x with respect to the upper surface of the interconnect layer 12 is not constant, and changes at the interface between the first insulating layer 13a and the second insulating layer 13b.

Specifically, in the cross-sectional view, the inclination angle α of the inner surface of the via hole 13x positioned in the first insulating layer 13a with respect to the upper surface of the interconnect layer 12 is larger than the inclination angle β of the inner surface of the via hole 13x positioned in the second insulating layer 13b with respect to the upper surface of the interconnect layer 12. The inclination angle α is, for example, 70 degrees or more and less than 90 degrees. β is, for example, 30 degrees or more and less than 60 degrees. In FIG. 1B, a dashed line L is an imaginary line parallel to the upper surface of the interconnect layer 12.

The via hole 13x is, for example, circular in plan view. In this case, the via hole 13x positioned in the first insulating layer 13a has an opening diameter of about 40 μm on the interconnect layer 12 side, and has an opening diameter of about 50 μm on the second insulating layer 13b side. The via hole 13x positioned in the second insulating layer 13b has an opening diameter on the first insulating layer 13a side that is the same as the opening diameter, on the second insulating layer 13b side, of the via hole 13x positioned in the first insulating layer 13a. The via hole 13x positioned in the second insulating layer 13b has an opening diameter of about 25 to 30 μm on the insulating layer 15 side.

The interconnect layer 14 fills the via hole 13x to be electrically connected to the interconnect layer 12, and extends from inside the via hole 13x and along the upper surface of the insulating layer 13 (i.e., the upper surface 13u of the second insulating layer 13b). Specifically, the interconnect layer 14 includes a via interconnect filled in the via hole 13x and an interconnect pattern formed on the upper surface of the insulating layer 13. The interconnect pattern of the interconnect layer 14 is electrically connected to the interconnect layer 12 via the via interconnect. The material of the interconnect layer 14 and the thickness of the interconnect pattern are, for example, the same as those of the interconnect layer 12.

The insulating layer 15 is an interlayer insulating layer formed to cover the interconnect layer 14 on the upper surface of the insulating layer 13. The insulating layer 15 includes a first insulating layer 15a covering the upper surface and the side surfaces of the interconnect layer 14, and a second insulating layer 15b laminated on the first insulating layer 15a. The details of the first insulating layer 15a and the second insulating layer 15b are the same as those of the first insulating layer 13a and the second insulating layer 13b.

The insulating layer 15 has at least one via hole 15x. The via hole 15x penetrates the insulating layer 15 and exposes the upper surface of the interconnect layer 14. The details of the via hole 15x are the same as those of the via hole 13x.

The interconnect layer 16 fills the via holes 15x to be electrically connected to the interconnect layer 14, and extends from inside the via hole 15x and along the upper surface of the insulating layer 15 (i.e., the upper surface of the second insulating layer 15b). Specifically, the interconnect layer 16 includes a via interconnect filled in the via hole 15x and an interconnect pattern formed on the upper surface of the insulating layer 15. The interconnect pattern of the interconnect layer 16 is electrically connected to the interconnect layer 14 via the via interconnect. The material of the interconnect layer 16 and the thickness of the interconnect pattern are, for example, the same as those of the interconnect layer 12.

The solder resist layer 17 is a protective insulating layer located as an outermost layer on the first side of the interconnect substrate 1, and is formed on the upper surface of the insulating layer 15 so as to cover the interconnect layer 16. The solder resist layer 17 may be formed of, for example, a photosensitive resin mainly composed of an epoxy-based resin or the like. The thickness of the solder resist layer 17 is, for example, about 15 to 35 μm.

The solder resist layer 17 has at least one opening 17x. The opening 17x penetrates the solder resist layer 17 and exposes the upper surface of the interconnect layer 16. The interconnect layer 16 exposed in the opening 17x may be used, for example, as a pad for electrical connection with an electronic component such as a semiconductor chip.

The surface of the interconnect layer 16 exposed in the opening 17x may have a metal layer formed thereon, or may have an organic film formed thereon by applying an oxidation prevention treatment such as OSP (organic solderability preservative) treatment. Examples of the metal layer include an Au layer, a Ni/Au layer (i.e., a metal layer in which a Ni layer and an Au layer are laminated in this order), a Ni/Pd/Au layer (i.e., a metal layer in which a Ni layer, a Pd layer, and an Au layer are laminated in this order), and a Sn layer.

The insulating layer 23 is an interlayer insulating layer formed so as to cover the interconnect layer 22 on the second surface 10b of the core layer 10. The insulating layer 23 includes a first insulating layer 23a covering the lower surface and the side surfaces of the interconnect layer 22, and a second insulating layer 23b laminated on the first insulating layer 23a. The details of the first insulating layer 23a and the second insulating layer 23b are the same as those of the first insulating layer 13a and the second insulating layer 13b.

The insulating layer 23 has at least one via hole 23x. The via hole 23x penetrates the insulating layer 23 and exposes the lower surface of the interconnect layer 22. The via hole 23x has a shape that is oriented upside down with respect to the via hole 13x. Other details of the via hole 23x are the same as those of the via hole 13x.

The interconnect layer 24 fills the via hole 23x to be electrically connected to the interconnect layer 22, and extends from inside the via hole 23x and along the lower surface of the insulating layer 23 (i.e., the lower surface of the second insulating layer 23b). More specifically, the interconnect layer 24 includes a via interconnect filled in the via hole 23x and an interconnect pattern formed on the lower surface of the insulating layer 23. The interconnect pattern of the interconnect layer 24 is electrically connected to the interconnect layer 22 via the via interconnect. The material of the interconnect layer 24 and the thickness of the interconnect pattern are, for example, the same as those of the interconnect layer 12.

The insulating layer 25 is an interlayer insulating layer formed to cover the interconnect layer 24 on the lower surface of the insulating layer 23. The insulating layer 25 includes a first insulating layer 25a covering the lower surface and the side surfaces of the interconnect layer 24, and a second insulating layer 25b laminated on the first insulating layer 25a. The details of the first insulating layer 25a and the second insulating layer 25b are the same as those of the first insulating layer 13a and the second insulating layer 13b.

The insulating layer 25 has at least one via hole 25x. The via hole 25x penetrates the insulating layer 25 and exposes the lower surface of the interconnect layer 24. The via hole 25x has a shape that is oriented upside down with respect to the via hole 13x. Other details of the via hole 25x are the same as those of the via hole 13x.

The interconnect layer 26 fills the via hole 25x and is electrically connected to the interconnect layer 26, and extends from inside the via hole 25x and along the lower surface of the insulating layer 25 (i.e., the lower surface of the second insulating layer 25b). Specifically, the interconnect layer 26 includes a via interconnect filled in the via hole 25x and an interconnect pattern formed on the lower surface of the insulating layer 25. The interconnect pattern of the interconnect layer 26 is electrically connected to the interconnect layer 24 via the via interconnect. The material of the interconnect layer 26 and the thickness of the interconnect pattern are, for example, the same as those of the interconnect layer 12.

The solder resist layer 27 is a protective insulating layer located as an outermost layer on the second side of the interconnect substrate 1, and is formed on the lower surface of the insulating layer 25 so as to cover the interconnect layer 26. The material of the solder resist layer 27 and the thickness thereof are, for example, the same as those of the solder resist layer 17.

The solder resist layer 27 has at least one opening 27x, and part of the lower surface of the interconnect layer 26 is exposed in the opening 27x. The plane shape of the opening 27x is, for example, circular. The interconnect layer 26 exposed in the opening 27x may be used as a pad for electrical connection with a mounting substrate (not illustrated) such as a motherboard. According to need, the lower surface of the interconnect layer 26 exposed in the opening 27x may have a previously-described metal layer formed thereon, or may have an organic film formed thereon by applying an oxidation prevention treatment such as OSP treatment.

### [Method of Making Interconnect Substrate]

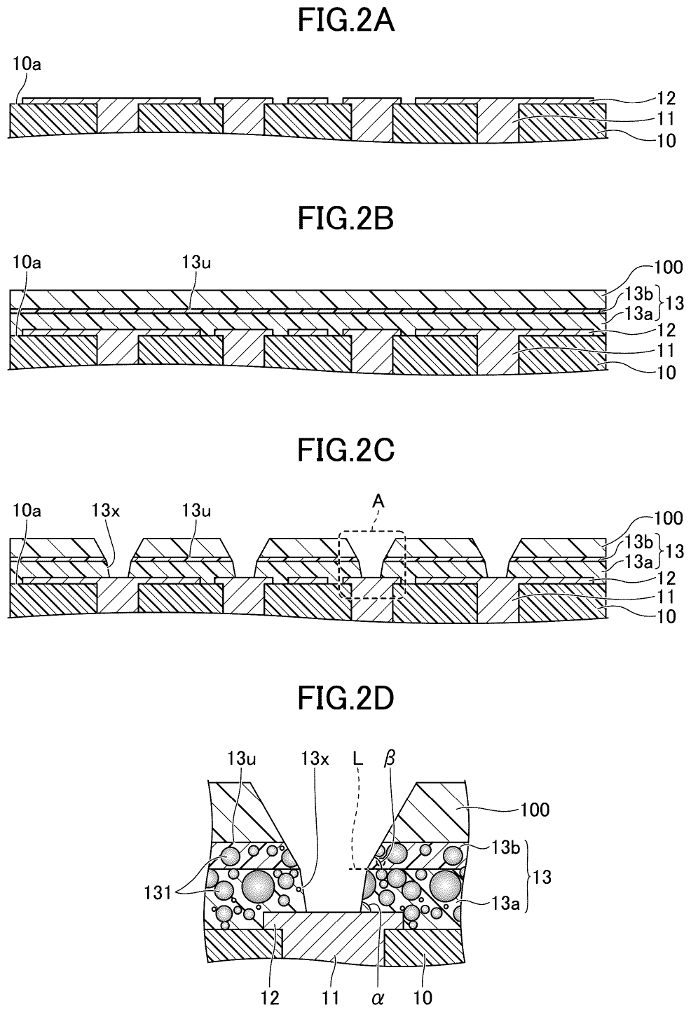

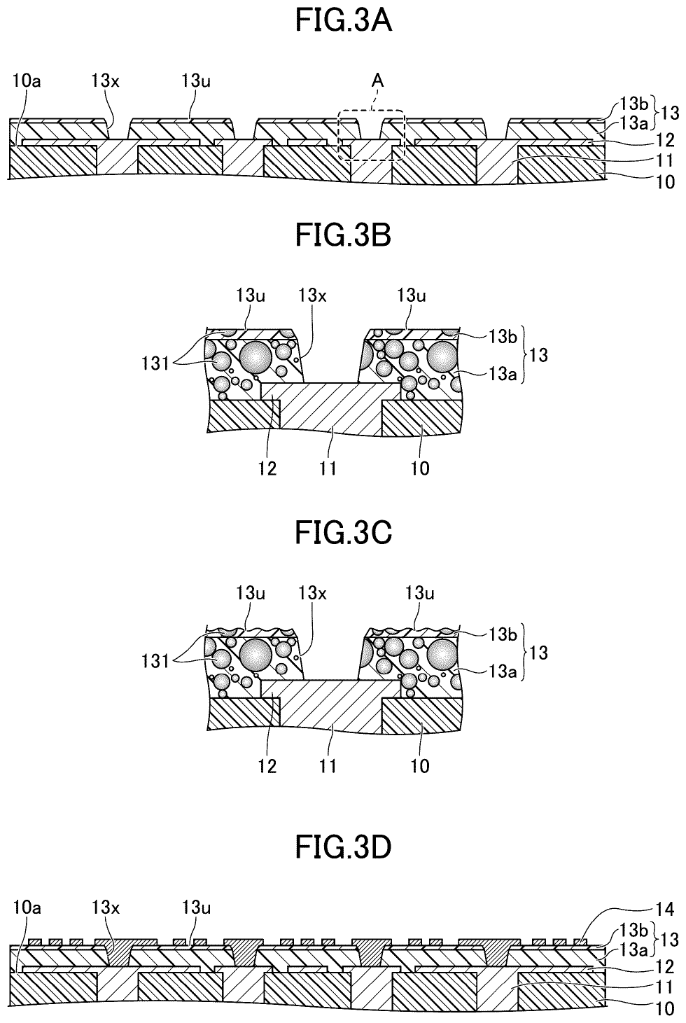

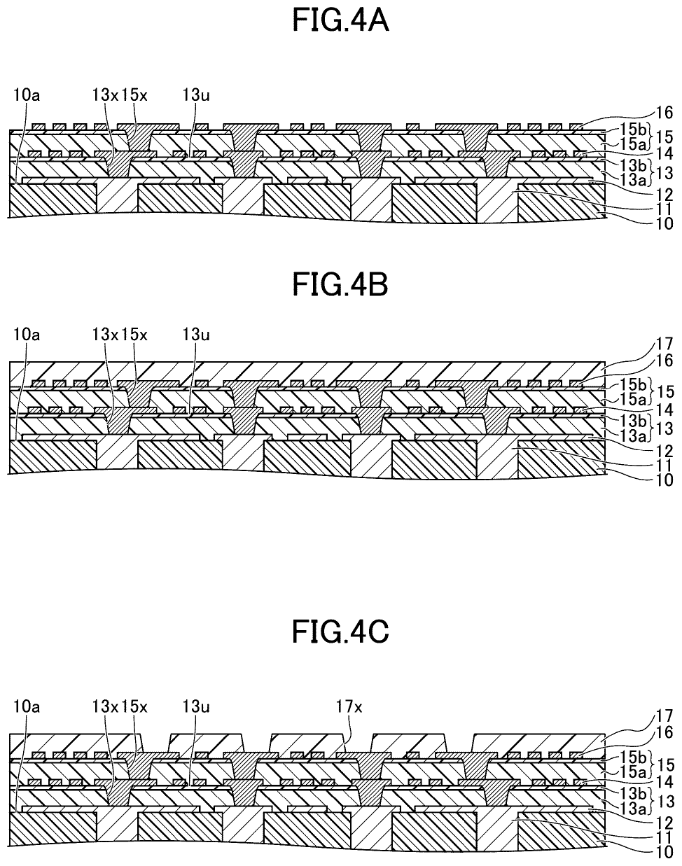

FIGS. 2A to 2D through FIGS. 4A to 4C are views illustrating an example of a manufacturing process of an interconnect substrate according to the first embodiment, and illustrate cross-sectional views corresponding to FIGS. 1A and 1B. FIG. 2D is an enlarged view of a portion A in FIG. 2C, and FIGS. 3B and 3C are enlarged views of a portion A in FIG. 3A.

Since the identical processes are performed on the first surface 10a side and the second surface 10b side of the core layer 10, only the first surface 10a side of the core layer 10 is illustrated and will be described. Although an example of a procedure of fabricating a single interconnect substrate will be described, an alternative procedure may be employed such that a plurality of portions to be interconnect substrates are first made, and are then divided into individual interconnect substrates.

First, in the step illustrated in FIG. 2A, the core layer 10 including the through interconnect 11 and the interconnect layer 12 is prepared. More specifically, for example, a laminated plate is prepared by forming a plain copper foil without patterning on the first surface 10a of the core layer 10 that is a glass epoxy substrate or the like. The prepared laminated plate is then subjected to thinning of the copper foil as needed, and then subjected to laser processing using a CO₂ laser or the like to make the through-holes 10x penetrating the core layer 10 and the copper foil.

Next, a desmear process is performed as necessary to remove residue of the resin contained in the core layer 10 that is adhering to the inner surfaces of the through-holes 10x. Then, a seed layer (copper or the like) covering the inner surfaces of the through-holes 10x is formed by, for example, an electroless plating method, a sputtering method, or the like, and an electroplating layer (copper or the like) is formed on the seed layer by an electroplating method using the seed layer as a power supply layer. As a result, the through-holes 10x are filled with the electroplating layer formed on the seed layer, and the interconnect layer 12 is formed as a laminate of the copper foil, the seed layer, and the electroplating layer on the first surface 10a of the core layer 10. Subsequently, the interconnect layer 12 is patterned into a predetermined plane shape by, for example, a subtractive method.

In the step illustrated in FIG. 2B, the insulating layer 13 is formed on the interconnect layer 12 on the first surface 10a of the core layer 10. The insulating layer 13 includes the first insulating layer 13a containing a filler, and the second insulating layer 13b laminated on the first insulating layer 13a, which is thinner than the first insulating layer 13a and contains less filler than the first insulating layer 13a. The amount of the filler contained in the first insulating layer 13a may be, for example, 70 wt % or more and 80 wt % or less. The amount of the filler contained in the second insulating layer 13b may be, for example, 0 wt % or more and less than 70 wt %.

Specifically, for example, a laminate in which the second insulating layer 13b and a resin film 100 are sequentially laminated on the first insulating layer 13a is prepared, and the laminate is arranged such that the first insulating layer 13a faces toward the interconnect layer 12. The first insulating layer 13a and the second insulating layer 13b are formed of, for example, a thermosetting resin in a B-stage state. Examples of the resin film 100 include, for example, a polyethylene terephthalate film and a polyethylene naphthalate film. The thickness of the resin film 100 may be, for example, 25 μm or more and 50 μm or less. The first insulating layer 13a and the second insulating layer 13b are then cured by being heated to a predetermined temperature and pressurized as necessary. At this point, the thickness of the second insulating layer 13b is, for example, 3 μm or more and 5 μm or less. A peelable release layer is provided between the upper surface 13u of the second insulating layer 13b and the resin film 100.

In the step illustrated in FIGS. 2C and 2D, the via holes 13x penetrating the insulating layer 13 and exposing the upper surface of the interconnect layer 12 are formed in the insulating layer 13. The via holes 13x may be formed, for example, by directing a laser beam such as a CO₂ laser from the resin film 100 side. The resin film 100 containing no filler and the second insulating layer 13b containing a small amount of filler are easy to be processed by laser beam, and, thus, have relatively large aperture diameters as a result. In contrast, the first insulating layer 13a containing a large amount of filler is difficult to be processed by laser beam, and, thus have relatively small aperture diameters.

That is, the inner surface of the via hole 13x is inclined relative to the direction perpendicular to the upper surface of the interconnect layer 12 such that the via hole 13x widens with an increase in the distance from the interconnect layer 12 in the thickness direction. The inclination angle of the inner surface of the via hole 13x with respect to the upper surface of the interconnect layer 12 is not constant, and changes at the interface between the first insulating layer 13a and the second insulating layer 13b. Specifically, in the cross-sectional view, the inclination angle α of the inner surface of the via hole 13x positioned in the first insulating layer 13a with respect to the upper surface of the interconnect layer 12 is larger than the inclination angle β of the inner surface of the via hole 13x positioned in the second insulating layer 13b and the resin film 100 with respect to the upper surface of the interconnect layer 12. The inclination angle α is, for example, 70 degrees or more and less than 90 degrees. β is, for example, 30 degrees or more and less than 60 degrees.

Although it is not essential to use the resin film 100 in the step illustrated in FIG. 2B, the provision of the resin film 100 on the upper surface 13u of the second insulating layer 13b allows for an increase in the power of the laser beam to be shone. Therefore, the inclination angles α and β can be increased as compared with the case where the resin film 100 is not disposed. Further, the provision of the resin film 100 on the upper surface 13u of the second insulating layer 13b effectively reduces the likelihood of foreign matter or the like adhering to the upper surface 13u of the second insulating layer 13b.

In the step illustrated in FIGS. 3A and 3B, the resin film 100 is removed, and, then, the entire insulating layer 13 is subjected to plasma treatment to thin the second insulating layer 13b. For the plasma treatment, for example, a gas composed of oxygen (O₂) and methane tetrafluoride (CF₄) may be used. Use of a gas containing O₂ in the plasma treatment effectively facilitates decomposition of the resin. Further, use of a gas containing O₂ in the plasma treatment serves to oxidize the surface of the filler, thereby enhancing the hydrophilicity. As a result, an etchant used in the desmear process described later may uniformly spread over the upper surface 13u of the second insulating layer 13b, which allows the upper surface 13u of the second insulating layer 13b to be uniformly roughened. Ar gas may alternatively be used in the plasma treatment. By the plasma treatment, the second insulating layer 13b is etched by about 1 to 3 μm, and the thickness of the second insulating layer 13b after the plasma treatment is, for example, 1 μm or more and 2 μm or less.

In the step illustrated in FIG. 3C, the entire insulating layer 13 is desmeared. This effectively removes the the resin residue of insulating layer 13 adhering to the upper surface of the interconnect layer 12 exposed at the bottom of the via holes 13x, and roughens the upper surface 13u of the second insulating layer 13b of the insulating layer 13. The roughness of the upper surface 13u of the second insulating layer 13b after the desmear process is, for example, 250 nm or more and 300 nm or less in terms of the arithmetic average roughness Ra. Since the second insulating layer 13b contains a small amount of filler, the upper surface 13u of the second insulating layer 13b does not become filler-rich even after the desmear process is performed.

The desmear process may include a wet etching step. The desmear process may include a swelling step before the wet etching step. In the swelling step, the insulating layer 13 having the via holes 13x is immersed in a swelling liquid for a predetermined time. This allows the resin residue to be easily removed in the etching step. Further, swelling the insulating layer 13 serves to improve the adhesion between the insulating layer 13 obtained through the etching step and the interconnect layer 14 formed thereafter. After the swelling step, the wet etching step may be performed. In the wet etching step, for example, an etching solution such as sodium permanganate or potassium permanganate may be used. After the etching wet step, post-treatment (neutralization) with a reducing agent solution is preferably performed.

In the step illustrated in FIG. 3D, the interconnect layer 14 is formed that fills the via holes 13x to be electrically connected to the interconnect layer 12 and that extends from inside the via holes 13x and along the upper surface of the insulating layer 13. The interconnect layer 14 includes via interconnects filled in the via holes 13x and interconnect patterns formed on the upper surface of the insulating layer 13. The interconnect patterns of the interconnect layer 14 are electrically connected to the interconnect layer 12 exposed at the bottom of the via holes 13x. The interconnect layer 14 may be formed by any of various interconnect forming methods such as a semi-additive method or a subtractive method.

When the interconnect layer 14 is formed by a semi-additive method, for example, a seed layer made of copper is formed by electroless plating on the upper surface of the insulating layer 13 (i.e., the upper surface 13u of the second insulating layer 13b), the inner surfaces of the via holes 13x, and the upper surface of the interconnect layer 12 exposed in the via holes 13x. Then, a plating resist pattern having openings matching the shapes of the interconnect patterns of the interconnect layer 14 is formed on the seed layer, and an electroplating layer is deposited on the seed layer exposed at the openings of the plating resist pattern by electroplating of copper or the like utilizing the seed layer as a power The supply layer. plating resist pattern is subsequently removed, and the seed layer exposed outside the electroplating layer is removed by etching using the electroplating layer as a mask. This procedure enables the fabrication of the interconnect layer 14 having the via interconnects and the interconnect patterns. In this case, the structure of the interconnect layer 14 is such that the electroplating layer is laminated on the seed layer.

As described above, the upper surface 13u of the second insulating layer 13b does not become filler-rich, and the roughness of the upper surface 13u of the second insulating layer 13b is, for example, 250 nm or more and 300 nm or less in terms of the arithmetic average roughness Ra. With this arrangement, excellent adhesion is obtained between the upper surface 13u of the second insulating layer 13b and the seed layer of the interconnect layer 14. As a result, the risk of occurrence of interconnect floating in the interconnect layer 14 is reduced.

In the step illustrated in FIG. 4A, the same steps as those illustrated in FIG. 2B to FIG. 3D are repeated to form the insulating layer 15 and the interconnect layer 16.

In the step illustrated in FIG. 4B, the solder resist layer 17 is formed on the upper surface of the insulating layer 15 so as to cover the interconnect layer 16. The solder resist layer 17 may be formed, for example, by applying a photosensitive epoxy-based insulating resin in a liquid or paste form to the upper surface of the insulating layer 15 so as to cover the interconnect layer 16 by a screen printing method, a roll coating method, a spin coating method, or the like. Alternatively, a photosensitive epoxy-based insulating resin film may be laminated on the upper surface of the insulating layer 15 so as to cover the interconnect layer 16.

In the step illustrated in FIG. 4C, the solder resist layer 17 is exposed and developed to form the openings 17x in the solder resist layer 17 for exposing part of the upper surface of the interconnect layer 16 (photolithography method). The plane shape of the openings 17x is, for example, circular. The diameters of the openings 17x may be designed freely in accordance with a device (i.e., semiconductor chip or the like) to be connected. According to need, the surface of the interconnect layer 16 exposed in the openings 17x may have a previously-described metal layer formed thereon, or may have an organic film formed thereon by applying an oxidation prevention treatment such as OSP treatment. By following these steps, the fabrication of the interconnect substrate 1 is completed.

As described above, the manufacturing process of the interconnect substrate 1 includes the step of thinning the second insulating layer 13b by performing a plasma treatment between the step of forming the via holes 13x penetrating the first insulating layer 13a and the second insulating layer 13b to expose the upper surface of the interconnect layer 12 and the step of performing a desmear process.

As was described with reference to FIGS. 2C and 2D, in cross-sectional view, the inclination angle α of the inner surface of the via hole 13x located in the first insulating layer 13a with respect to the upper surface of the interconnect layer 12 is larger than the inclination angle β of the inner surface of the via hole 13x located in the second insulating layer 13b and the resin film 100 with respect to the upper surface of the interconnect layer 12. In other words, the inclination angle β is smaller than the inclination angle α. When the second insulating layer 13b is thick, thus, the opening diameters of the via holes 13x in the upper surface 13u of the second insulating layer 13b becomes larger, and the interval between adjacent ones of the via holes 13x becomes narrower. As a result, adjacent interconnects of the interconnect layer 14 may be short-circuited. order to avoid such short-circuiting between the interconnects of the interconnect layer 14, the interval between the adjacent via holes 13x may be widened. However, this arrangement ends up decreasing the interconnect density of the interconnect layer 14. In the interconnect substrate 1, on the other hand, the second insulating layer 13b is thinned by plasma treatment, so that the interval between the adjacent via holes 13x becomes wider than when the second insulating layer 13b is not thinned. As a result, even when the interconnect layer 14 is formed with high density, the possibility of short-circuiting between the adjacent interconnects of the interconnect layer 14 is effectively reduced. The same applies to other interconnect layers.

Since the second insulating layer 13b contains less filler than the first insulating layer 13a, a greater thickness leads to a greater disadvantage in terms of dielectric characteristics. In the interconnect substrate 1, thinning the second insulating layer 13b serves to reduce its effect on the dielectric characteristics. Specifically, the dielectric characteristics of the insulating layer 13 are predominantly determined by the effect of the first insulating layer 13a, which is thicker than the second insulating layer 13b and contains more filler than the second insulating layer 13b. It is thus possible to achieve the interconnect substrate 1 with excellent electrical characteristics and reduced loss of electrical signals.

Although the preferred embodiments have been described in detail above, the present invention is not limited to the above-described embodiments, and various modifications and substitutions can be made to the above-described embodiments without departing from the scope of the claims.

For example, in the step illustrated in FIG. 2B, the resin film 100 may not be used. In this case, for example, the first insulating layer 13a is formed by laminating and curing a semi-cured thermosetting resin film mainly composed of an epoxy-based resin or the like on the first surface 10a of the core layer 10 so as to cover the interconnect layer 12. Further, the second insulating layer 13b may be formed by laminating and curing a semi-cured thermosetting resin film mainly composed of an epoxy-based resin or the like on the first insulating layer 13a. The first insulating layer 13a and the second insulating layer 13b may be cured simultaneously. Alternatively, instead of laminating an epoxy-based resin film or the like, a liquid or paste epoxy-based resin or the like may be coated and cured as the first insulating layer 13a and the second insulating layer 13b.

Further, the above-described embodiment has been directed to an example in which the present invention is applied to an interconnect substrate manufactured by a build-up method and having a core layer. The present invention may alternatively be applied to a coreless interconnect substrate manufactured by a build-up method. The present invention is applicable to various interconnect substrates without being limited these examples.

According to at least one embodiment, an interconnect substrate is provided in which the risk of short-circuiting between adjacent interconnects is reduced.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The present disclosures non-exhaustively include the subject matter set out in the following clauses.

Clause 1. A method of making an interconnect substrate, comprising:
forming an insulating layer on a first interconnect layer, the insulating layer including a first insulating layer containing a filler and a second insulating layer laminated on the first insulating layer, the second insulating layer being thinner than first the insulating layer and containing less filler than the first insulating layer;
forming a via hole penetrating the insulating layer and exposing an upper surface of the first interconnect layer;
thinning the second insulating layer by applying a plasma treatment after the forming the via hole;
performing a desmear process after the thinning;
forming, after the performing the desmear process, a second interconnect layer filling the via hole and electrically connected to the first interconnect layer, the second interconnect layer extending from inside the via hole and along an upper surface of the second insulating layer.

Clause 2. The method as recited in Clause 1, wherein the forming the insulating layer includes preparing a laminate in which the second insulating layer and a resin film are sequentially laminated on the first insulating layer, and arranging the laminate such that the first insulating layer faces toward the first interconnect layer, and
wherein the forming the via hole includes directing a laser beam to the laminate from a direction of the resin film to form the via hole.

Clause 3. The method as recited in Clause 1, wherein as a result of the forming the via hole, an inside surface of the via hole is inclined with respect to a direction perpendicular to the upper surface of the first interconnect layer in cross-sectional view, and an angle of the inside surface of the via hole in the first insulating layer with respect to the upper surface of the first interconnect layer is larger than an angle of the inside surface of the via hole in the second insulating layer with respect to the upper surface of the first interconnect layer.

Clause 4. The method as recited in Clause 1, wherein a thickness of the second insulating layer after the plasma treatment is 1 μm or more and 2 μm or less.

Clause 5. The method as recited in Clause 1, wherein a roughness of the upper surface of the second insulating layer after the desmear process is 250 nm or more and 300 nm or less in terms of arithmetic average roughness Ra.

Clause 6. The method as recited in Clause 1, wherein an amount of the filler contained in the first insulating layer is 70 wt % or more.

What is claimed is:

1. An interconnect substrate comprising:
a first interconnect layer;
an insulating layer formed on the first interconnect layer and containing a filler;
a via hole penetrating the insulating layer and reaching an upper surface of the first interconnect layer; and
a second interconnect layer filling the via hole and electrically connected to the first interconnect layer, the second interconnect layer extending from inside the via hole and along an upper surface of the insulating layer,
wherein the insulating layer includes a first insulating layer covering the first interconnect layer and a second insulating layer laminated on the first insulating layer,
the second insulating layer is thinner than the first insulating layer,
an amount of the filler contained in the second insulating layer is smaller than an amount of the filler contained in the first insulating layer,
in cross-sectional view, an inner surface of the via hole is inclined relative to a direction perpendicular to the upper surface of the first interconnect layer,
in the cross-sectional view, an angle of the inner surface of the via hole in the first insulating layer with respect to the upper surface of the first interconnect layer is larger than an angle of the inner surface of the via hole in the second insulating layer with respect to the upper surface of the first interconnect layer.

2. The interconnect substrate as claimed in claim 1, wherein a thickness of the second insulating layer is 1 μm or more and 2 μm or less.

3. The interconnect substrate as claimed in claim 1, wherein a roughness of an upper surface of the second insulating layer is 250 nm or more and 300 nm or less in terms of an arithmetic average roughness Ra.

4. The interconnect substrate as claimed in claim 1, wherein an amount of the filler contained in the first insulating layer is 70 wt % or more.

5. The interconnect substrate as claimed in claim 1, wherein in the cross-sectional view, the angle of the inner surface of the via hole in the first insulating layer with respect to the upper surface of the first interconnect layer is from 70 degrees to 90 degrees, and the angle of the inner surface of the via hole in the second insulating layer with respect to the upper surface of the first interconnect layer is from 30 degrees to 60 degrees.
